(19) United States
(12) Patent Application Publication
(10) Pub. No.: US 2006/0032740 A1
(43) Pub. Date: Feb. 16, 2006

(54) Slotted thin-film sputter deposition targets for ferromagnetic materials

(75) Inventors: Matthew T. Willson, New Milford, CT (US); Henry L. Grohman, Wappingers Falls, NY (US)

Correspondence Address: HISCOCK & BARCLAY, LLP, 2000 HSBC PLAZA, ROCHESTER, NY, 14604-2404, US

(73) Assignee: Williams Advanced Materials, Inc.

(21) Appl. No.: 11/200,930

(22) Filed: Aug. 10, 2005

Related U.S. Application Data
(60) Provisional application No. 60/601,865, filed on Aug. 16, 2004.

(51) Int. Cl. C23C 14/35

(52) U.S. Cl. 204/298.12; 204/298.13; 204/298.19

(57) ABSTRACT

A slotted sputtering target for a magnetron sputtering system for thin-film deposition particularly suited for ferromagnetic target materials such as cobalt, nickel, and iron or an alloy including more than one of these elements.

### CROSS-REFERENCE TO RELATED APPLICATIONS

This application claims priority from U.S. Provisional Patent Application Ser. No. 60/601,865, filed Aug. 16, 2004.

### FIELD OF THE INVENTION

The invention relates generally to a target source for thin film sputter deposition and more particularly to a target source made from ferromagnetic material.

### BACKGROUND OF THE INVENTION

Sputtering deposition systems that utilize target sources are found in a variety of applications. Sputtering deposition systems present a well known technique for applying a thin layer of source material on a substrate. In operation, a high energy source of ions bombard a target source with sufficient energy to cause energized atoms to leave the target source, form a particle flux, and then deposit as thin film on a substrate.

Various techniques of sputter deposition are known in the art. U.S. Pat. No. 4,693,805 discloses a method and apparatus for sputtering a dielectric target. The apparatus comprises a target, an anode, and an auxiliary electrode wherein each of these elements is electrically isolated from a grounded chamber containing plasma. In operation, the anode and target are connected across a power supply which applies a series of waveforms, rendering the target positive with respect to the plasma and thereby sputtering it.

Because of the nature of magnetic cathode sputter deposition, the target sources erode over a period of time, eventually becoming unsuitable for their intended purpose. Once the target is substantially eroded, the apparatus is taken off line and the target is replaced. This down time results in excessive costs and losses in efficiency.

A proposed method of increasing the life of a target is to increase its thickness. When the target is thick, sputtering may proceed for an extended period of time until its useful working thickness is consumed. Targets made from ferromagnetic materials face problems not encountered by targets produced of other, non-magnetic materials. More particularly, magnetron cathode sputtering requires the application of a magnetic field to the target, wherein the applied magnetic field transmits through the target, creating a discharge plasma on the front of the target. The working surface of the target is then atomized by argon plasma, thereby distributing a layer of atoms from the target material onto the surface of an adjacent substrate. The process serves to form a thin film on the substrate.

Generally, because of their high magnetic permeability and because magnetic lines of force decrease relative to target thickness, ferromagnetic sputter targets are typically thinner than non-magnetic sputter targets, thereby permitting a sufficient magnetic field to permeate the sputtering surface to sustain sufficient sputtering plasma. Typically, ferromagnetic targets are less than 0.25 inch thick, whereas non-ferromagnetic targets may be substantially thicker. Because ferromagnetic targets are required to be thinner, replacement of the targets and associated equipment down time occur more often and have become a concern.

Attempts have been made to overcome the aforementioned issues associated with ferromagnetic targets. U.S. Pat. No. 4,324,631 discloses a method of magnetron sputtering of magnetic materials wherein the target material is initially heated to its Curie temperature, thereby rendering the material non-magnetic, and maintaining the target temperature at or above such temperature during the sputtering process. While the process addressed problems associated with ferromagnetic targets, the target must be continually monitored by a temperature-sensing device, and a fluid coolant which flows in thermal communication with the target must be controlled by a thermostat. The additional steps and cost associated with the added equipment serve to negate much of the benefits derived by the process.

Therefore, what is needed in the art is a ferromagnetic sputtering target, having a larger usable volume, but still allows for sufficient magnetic field to permeate the sputtering surface to sustain sufficient sputtering plasma.

Furthermore, what is needed in the art is such a sputtering target with increased longevity, that is cost effective and serves to reduce down time associated with target replacement.

### SUMMARY OF THE INVENTION

The invention comprises, in one form thereof, a slotted sputtering target for a magnetron sputtering system for thin-film deposition. The slotted sputtering target is particularly suited for ferromagnetic target materials such as cobalt, nickel, and iron or an alloy consisting essentially of any of the above elements. The sputtering target includes a working surface and a recessed surface formed by a pattern of trenches in the working surface. The height of the recessed surface is low enough to allow a sufficient amount of magnetic flux pass through the target to form the required sputtering plasma. Therefore, the working surface may have an increased height, and thus a longer lifetime, than the ferromagnetic targets of the prior art. The invention includes an embodiment of the slotted sputtering target having a sculpted working surface and a recessed surface.

More particularly, the invention includes an extended life sputtering target for depositing a ferromagnetic material onto a substrate in a chamber of a sputtering apparatus. The apparatus uses a magnetic field passing through the target to produce a plasma field within the chamber. The target comprises a plate formed from the ferromagnetic material and has a supporting surface, a working surface substantially opposite to the supporting surface and from which atoms of the ferromagnetic material are caused by the plasma field to be detached from the target. The distance between the supporting surface and the working surface is greater than an optimum distance by which a sufficient plasma field can be created. The plate defines a plurality of grooves cut into the working surface and forms both discrete areas on the working surface and a recessed surface between the supporting surface and the working surface. The distance between the recessed surface and the supporting surface is sufficiently small and the area of the recessed surface is sufficiently large such that the plasma field in the chamber is sufficient to detach ferromagnetic material atoms from the working surface.

The invention further includes a magnetron sputtering system comprising means for defining a vacuum chamber, means for producing an ionized gas to be contained in the chamber, an electromagnet proximate to the vacuum chamber, and an extended life sputtering target according positioned within the chamber adjacent the electromagnet. The electromagnet forms the ionized gas into a torus shaped plasma field proximate to the working surface to detach atoms from the working surface. In one embodiment, the working surface of the target is non-planar such that the distance between the support surface and each discrete area of the working surface is substantially proportional to the rate of detachment of atoms from that discrete area.

An advantage of the present invention is that a ferromagnetic sputtering target having a greater thickness, but allows for sufficient magnetic field to permeate the sputtering surface to sustain sufficient sputtering plasma is provided.

A further advantage of the present invention is that a sputtering target with increased longevity, that is cost effective and serves to reduce down time associated with target replacement is provided.

### BRIEF DESCRIPTION OF THE DRAWINGS

The above-mentioned and other features and advantages of this invention, and the manner of attaining them, will become apparent and be better understood by reference to the following description of several embodiments of the invention in conjunction with the accompanying drawings, wherein:

FIG. 1 is a cross-section of a diagram of a magnetron sputtering system having a slotted sputtering target of the present invention;

FIG. 2A is a plan view of a first embodiment of the sputtering target of the present invention;

FIG. 2B is a side view of the sputtering target of FIG. 2A;

FIG. 2C is a cross-sectional view of the raised surface of FIG. 2A;

FIG. 2D is a cross-sectional view of the annular cutter tool;

FIG. 3A is a plan view of a second embodiment of the sputtering target of the present invention;

FIG. 3B is a side view of the sputtering target of FIG. 3A;

FIG. 3C is a thin-slice cross-sectional view of the sputtering target taken at line 3C-3C of FIG. 3A;

FIG. 3D is a detail of the plan view of the sputtering target shown in FIG. 3A;

FIG. 3E is a detail of the thin-slice cross-sectional view of the sputtering target shown in FIG. 3C;

FIG. 3F is a thin-slice cross-sectional view of the sputtering target taken at line 3F-3F of FIG. 3D;

FIG. 4A is a plan view of a third embodiment of the sputtering target of the present invention;

FIG. 4B is a side view of the sputtering target of FIG. 4A;

FIG. 4C is a cross-sectional view of the sputtering target taken at line 4C-4C of FIG. 4A;

FIG. 5A is a plan view of a fourth embodiment of the sputtering target of the present invention;

FIG. 5B is a side view of the sputtering target of FIG. 5A;

FIG. 6A is a plan view of a fifth embodiment of the sputtering target of the present invention;

FIG. 6B is a cross-sectional view of the sputtering target taken at line 6B-6B of FIG. 6A.

FIG. 7A is a plan view of a sixth embodiment of the sputtering target of the present invention;

FIG. 7B is a side view of the sputtering target of FIG. 7A;

FIG. 7C is a cross-sectional view of the sputtering target taken at line 7C-7C of FIG. 7A; and

FIG. 7D is a detail of the cross-sectional view of the sputtering target of FIG. 7C.

Corresponding reference characters indicate corresponding parts throughout the several views. The examples set out herein illustrate several embodiments of the invention but should not be construed as limiting the scope of the invention in any manner.

### DETAILED DESCRIPTION

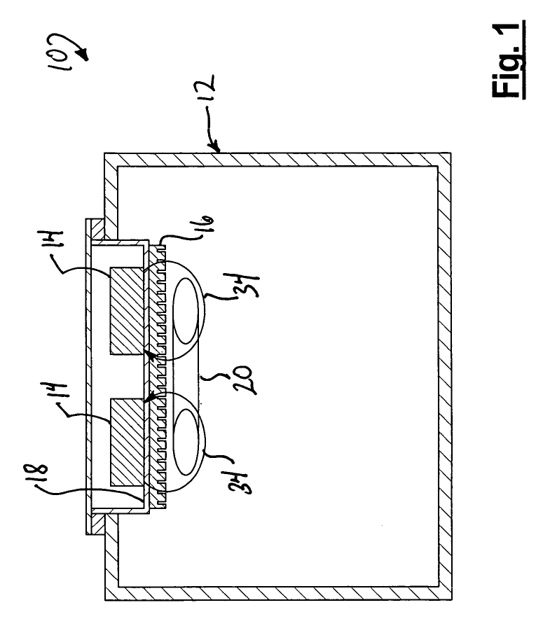

Referring to FIG. 1, there is shown a magnetron sputtering system having a slotted sputtering target of the present invention. The magnetron sputtering system 10 includes a vacuum chamber 12, an electromagnet 14, and a sputtering target 16.

The magnetron sputtering system 10 is a planar DC magnetron sputtering system such as the one sold by Trikon Technologies Limited Corporation under the trademark SIGMA, the one sold by Applied Materials, Inc. under the trademark ENDURA, and the one sold by Veeco Instruments Inc. under the trademark NEXUS. The vacuum chamber 12 is substantially sealed off from the ambient air and contains an ionized gas such as ionized argon. The electromagnet 14 is either a single electromagnet or a plurality of electromagnets mounted over a target backing plate 18 on top of the vacuum chamber 12. The magnetic field from the electromagnet 14 passes into the vacuum chamber 12 and forms a plasma ring 20 below the target backing plate 18. The target backing plate 18 is removable from vacuum chamber 12 such that the sputtering target 16 may be affixed to the backing plate 18 such as by solder, adhesive, or mechanical fasteners.

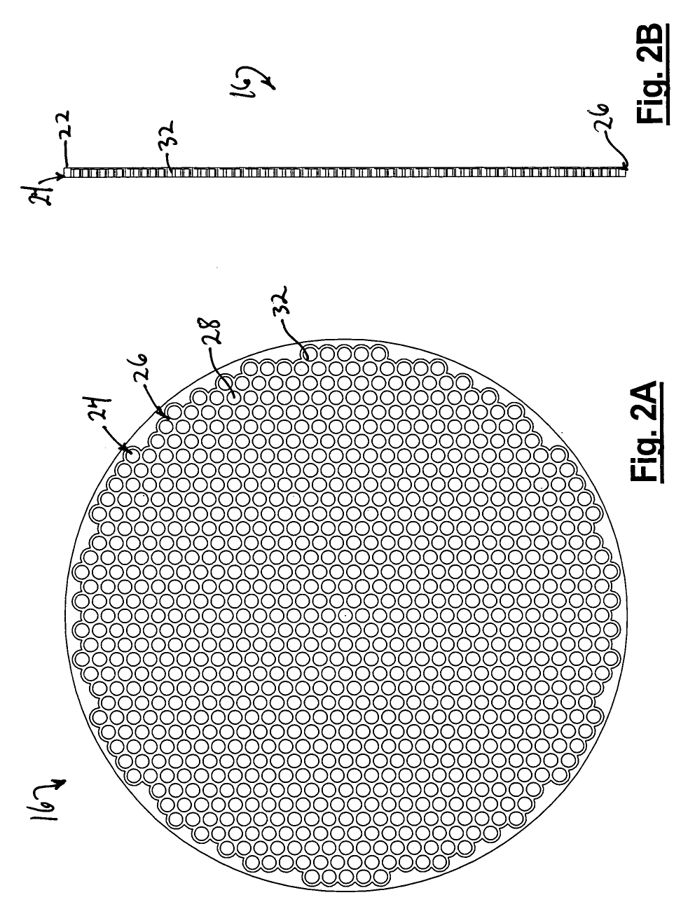

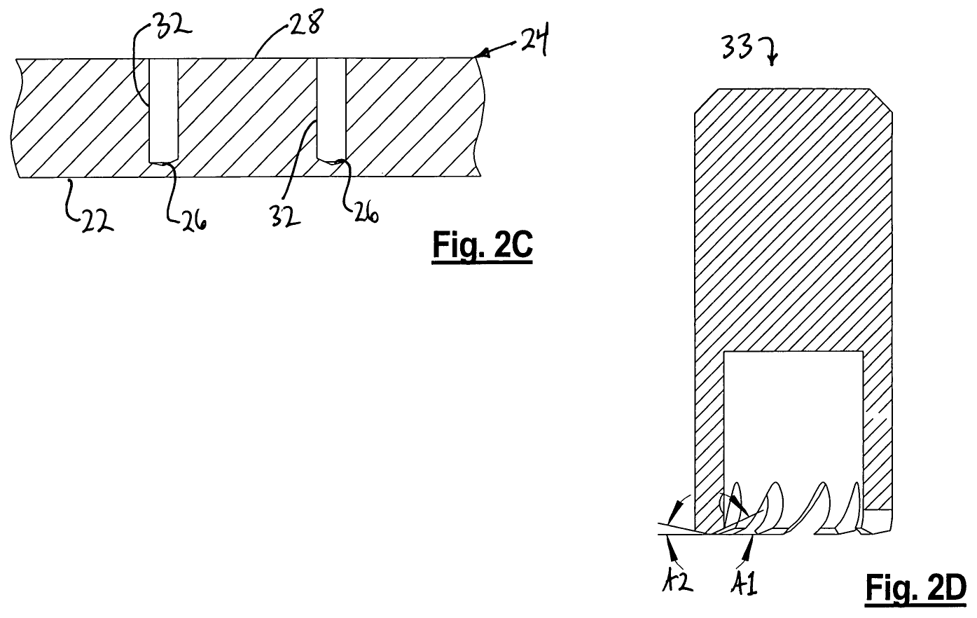

The sputtering target 16 is made of any material required for deposition on a substrate by the magnetron sputtering system 10. However, the slotted design of the sputtering target 16 is particularly useful for ferromagnetic materials such as nickel, cobalt, iron, and ferromagnetic alloys of those metals. Other useful compositions for such sputtering targets are the forgoing ferromagnetic materials and alloys with up to 40 atomic % boron and preferably up to 25 atomic % boron. Preferably, the targets have a purity of at least 99.0%, or more preferably the targets have a purity of 99.95%. However the purity and the materials that make up the alloy may vary according to the application. The sputtering target 16 shown in FIGS. 2A-2C includes a supporting surface 22, a working surface 24, and a recessed surface 26. The work surface 24 of the present configuration is made up of a plurality of raised substantially circular shapes 28. The recessed surface 26 together with the raised shapes 28 form a pattern of grooves or trenches 32 in the work surface 24 such as by cutting trenches 32 of optimal width and depth into the work surface 24. The trenches 32 are cut using an annular cutting tool 33, shown in FIG. 2D. According to the preferred embodiment, the annular cutting tool 33 has an inner diameter of about 0.300-in, an outer diameter of about 0.425-in, an inner angle (A1) of about 24°, and an outer angle (A2) of about 12°. The tool 33 is applied to the working surface 24 in step and repeat fashion to form the pattern of offset circular shapes 28. Alternatively, the sputtering target 16 is molded to form circular shapes 28 and trenches 32 to thereby provide the working surface 24 and the recessed surface 26. The distance from the supporting surface 22 to the work surface 24 is preferably about 0.200-in and the distance between the supporting surface 22 and the recessed surface 26 is preferably about 0.025-in. The work surface 24 is preferably over 60% of the overall horizontal surface of the sputtering target 16. Thus the sputtering target 16 provides ample work surface having a lifetime approaching that of a non-ferromagnetic target that has a 100% work surface while providing a thin portion to allow the required magnetic pass through flux and an anticipated target life of about three times that of known ferromagnetic wafer targets.

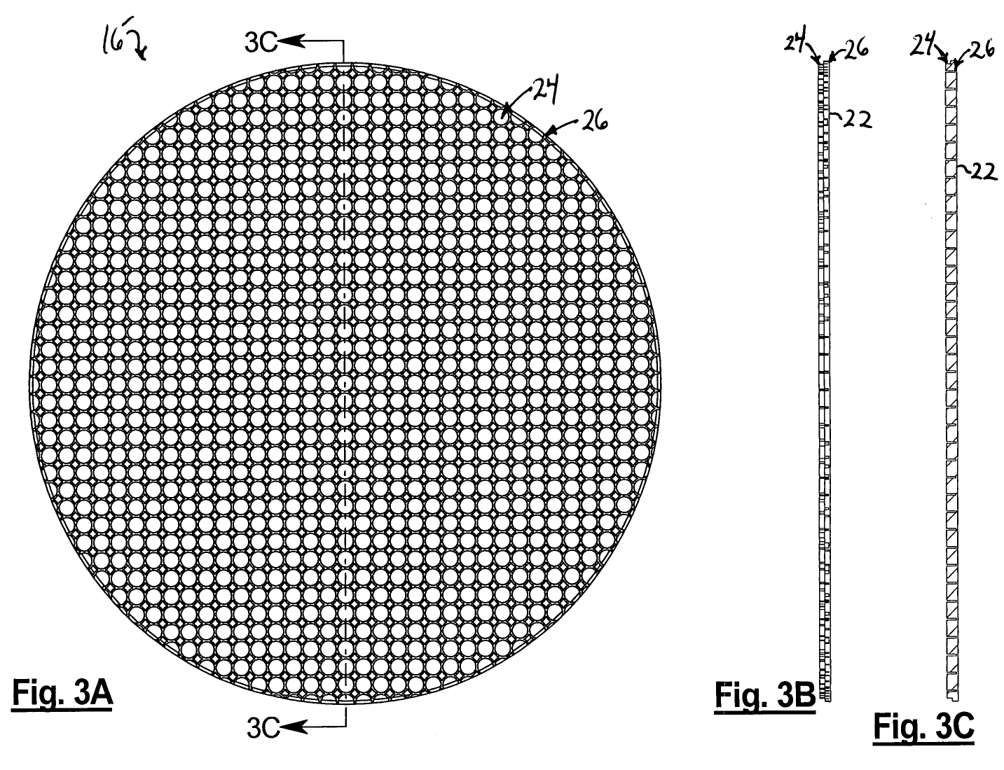

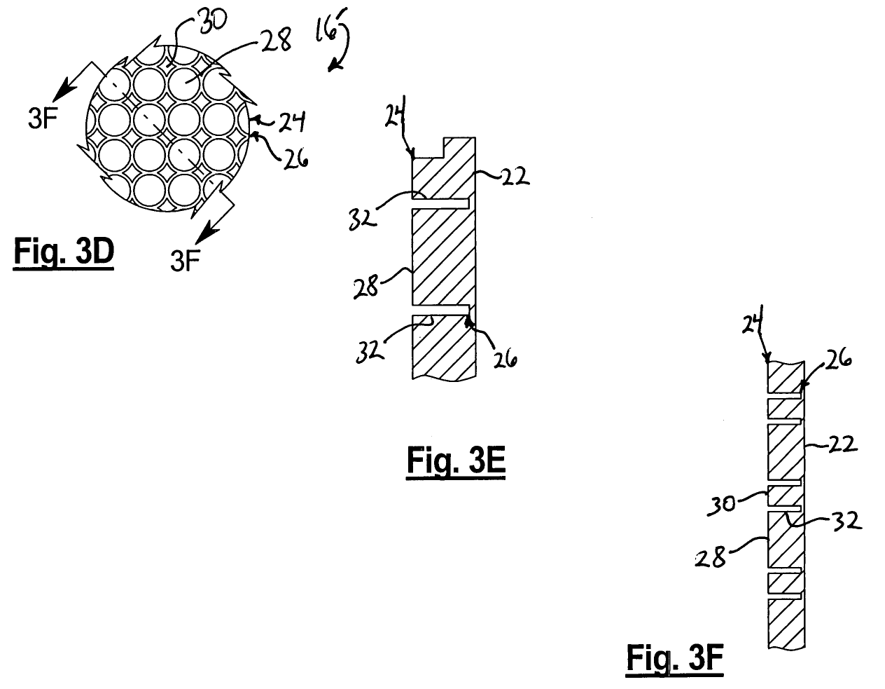

In a similar embodiment the annular cutting tool 33 is used to form circular and hypocycloidal shapes in the sputtering target 16′. Similar to the pattern shown in FIGS. 2A-2C, the sputtering target 16′ shown in FIGS. 3A-3F includes a supporting surface 22, a working surface 24, and a recessed surface 26. FIG. 3D shows that the work surface 24 of the present configuration is made up of a plurality of raised substantially circular shapes 28 and hypocycloidal shapes 30. FIGS. 3E and 3F show that the recessed surface 26 together with the raised shapes 28, 30 form a pattern of trenches 32 in the work surface 24 such as by cutting trenches 32 of optimal width and depth into the work surface 24, as described in the first embodiment. Alternatively, the sputtering target 16′ is molded to form circular shapes 28, hypocycloids 30, and trenches 32 to thereby provide the working surface 24 and the recessed surface 26. According to the present embodiment, the distance from the supporting surface 22 to the work surface 24 is about 0.600-in and the distance between the supporting surface 22 and the recessed surface 26 is about 0.060-in for a ratio of about 10 to 1. The work surface 24 is about 75% of the overall horizontal surface of the sputtering target 16′. Thus the sputtering target 16′ provides ample work surface having a lifetime approaching that of a non-ferromagnetic target that has a 100% work surface while providing a thin portion to allow the required magnetic pass through flux and an anticipated target life of about three times that of known ferromagnetic wafer targets.

In use, the sputtering target 16 (or 16′) is mounted onto the target backing plate 18 as shown in FIG. 1. More particularly, the supporting surface 22 is affixed to the target backing plate 18 by solder, adhesive, mechanical fasteners, or other suitable method. The electromagnet 14 is activated and a portion of the resultant magnetic field passes through the target backing plate 18 and the sputtering target 16 into the vacuum chamber 12. The magnetic field is represented by field lines 34. The plasma ring 20 is formed of the ionized gas by the magnetic field. The sputtering target 16 is positively charged to act as a cathode and the plasma ring 20 is negatively charged to act as an anode. Thus, ionized particles from the plasma ring 20 travel along the magnetic field to strike the work surface 24 of the sputtering target 16. The impact causes atoms from the sputtering target 16 to be released from the work surface 24 and to be subsequently deposited on a substrate (not shown).

A significant percentage of the magnetic field is required to pass through the sputtering target 16 into the vacuum chamber 12 in order to form a proper plasma ring 20. The percentage of the magnetic field that passes through the sputtering target 16 into the vacuum chamber 12 is called the percent pass through flux. The percent pass through flux has been measured for a sputtering target 16′ according to the second embodiment of the present invention. The measurement is taken by positioning a magnet near the supporting surface 22 and positioning a magnetic probe near the work surface 24, opposite to the magnet. The probe and the magnet are moved concurrently around the surface of the target in order to measure the pass through flux at several points around the surface of the target. A 12-in diameter target was used in the measurement, however, measurements were only taken in a 10-in diameter circle that is concentric with the target such that leakage of the magnetic field around the edges of the target doesn't interfere with the measurement of the pass through flux.

In the measurement of the slotted target according-to the present invention, the magnetic flux applied to the slotted target was about 298 Gauss and the average pass through flux was about 63 Gauss for a percent pass through flux of approximately 21.1%. The distance from the supporting surface 22 to the recessed surface 26 of the slotted target was 0.020-in and the distance from the supporting surface 22 to the work surface 24 was 0.203-in. The material of the slotted target was a ferromagnetic iron alloy containing about 35 atomic % cobalt.

By way of comparison, a non-slotted target according to the prior art was also measured. The measurement was carried out as described above on a 12-in diameter non-slotted target. The thickness of the non-slotted target was 0.080-in and the material used was the same as that used for the slotted target. The magnetic flux applied to the non-slotted target was about 483 Gauss and the average pass through flux was only about 9 Gauss for a percent pass through flux of approximately 1.9%.

Therefore the slotted target of the present invention provides a target having a greater percent pass through flux and a longer lifetime than the prior art. The longer target lifetime is due to the larger distance between the supporting surface 22 and the work surface 24 than the thickness of the non-slotted target used in the comparison.

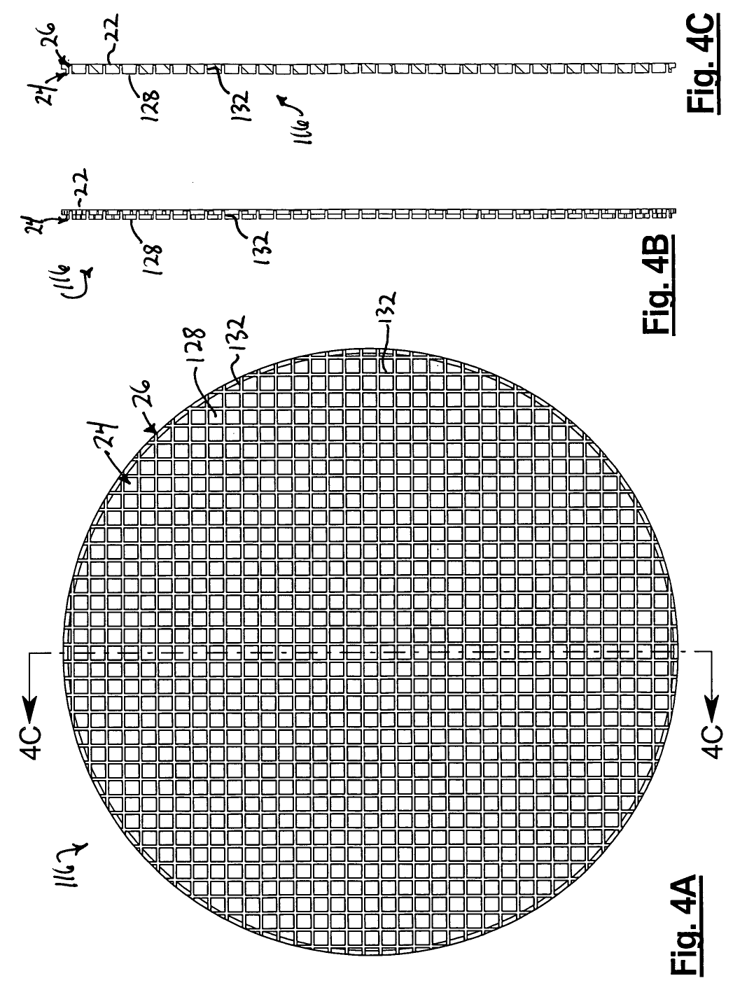

An alternate embodiment of the sputtering target is configured as shown in FIGS. 4A-4C. The sputtering target 116 has a substantially circular shape. The work surface 24 of the sputtering target 116 is made up of a plurality of polygons 128 and the recessed surface 26 is formed by a grid of trenches 132. The distance between the supporting surface 22 and the recessed surface 26 of the sputtering target 116 is preferably about 0.020-in. The work surface 24 is preferably about 70% of the overall horizontal surface of the sputtering target 116.

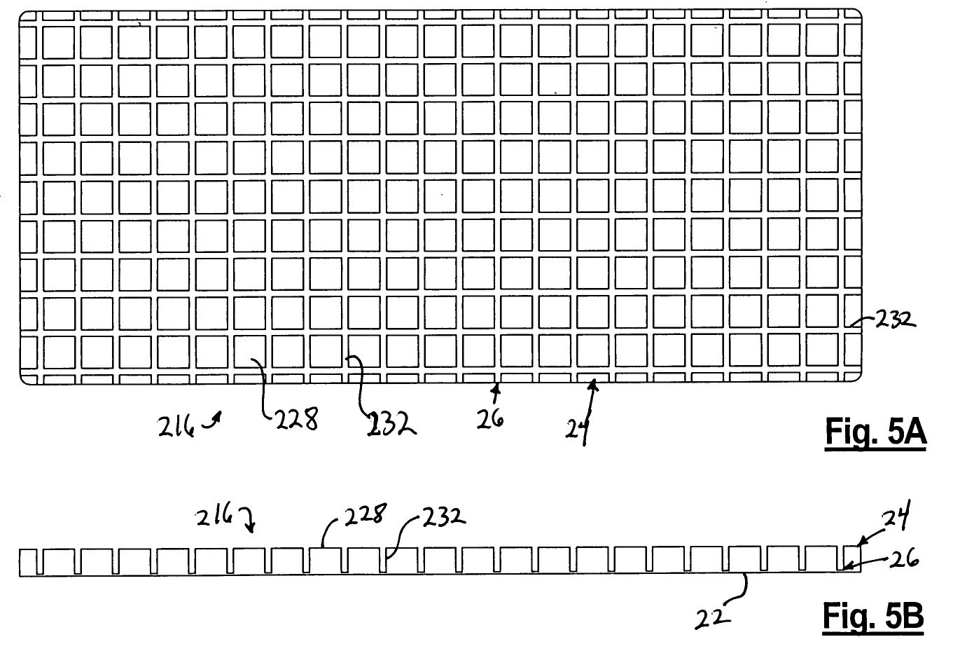

Another example of an alternative embodiment is shown in FIGS. 5A and 5B. The sputtering target 216 is polygonal in shape. The work surface 24 of the sputtering target 216 is made up of a plurality of polygons 228 and the recessed surface 26 is formed by a grid of trenches 232. The distance between the supporting surface 22 and the recessed surface 26 of the sputtering target 216 is preferably about 0.020-in. The work surface 24 is preferably about 70% of the overall horizontal surface of the sputtering target 216.

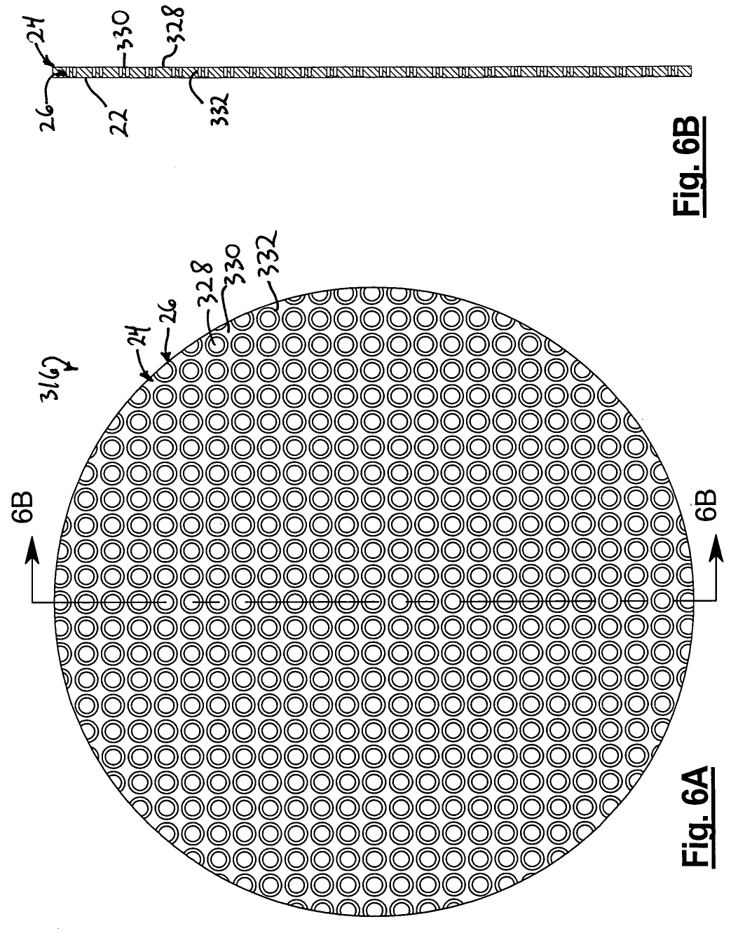

A further example of an alternate embodiment is shown in FIGS. 6A and 6B. The outer perimeter of the sputtering target 316 has a substantially circular shape in the present embodiment, however, the outer perimeter may be any shape. The work surface 24 is formed by a relatively uniform pattern of substantially circular trenches 332 that produce a number of substantially circular shapes 328 and a continuous field 330. The recessed surface 26 is formed by the pattern of trenches 332. The distance between the supporting surface 22 and the recessed surface 26 of the sputtering target 316 is preferably about 0.020-in. The work surface 24 is preferably about 70% of the overall horizontal surface of the sputtering target 316.

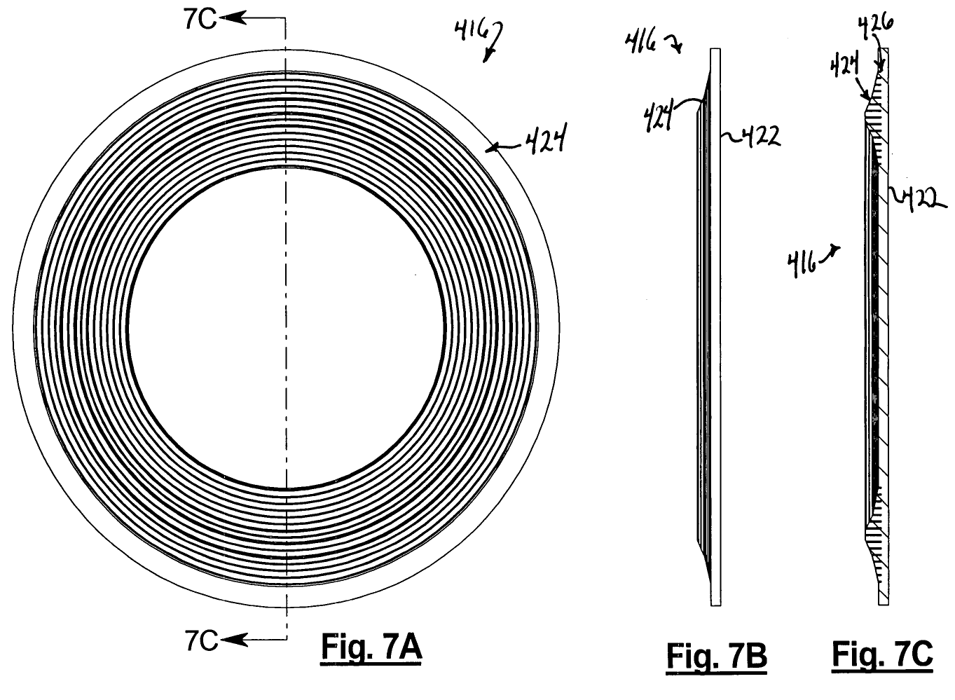

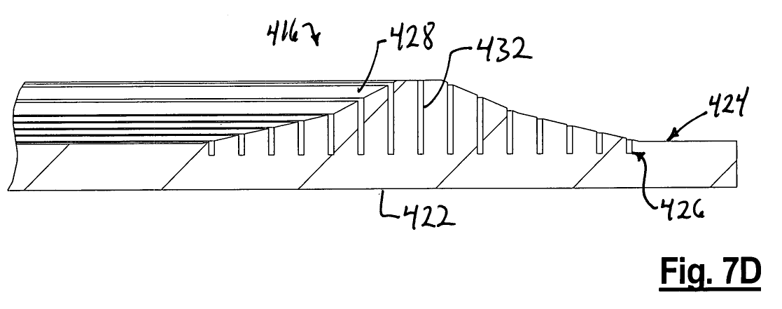

In a further embodiment shown in FIGS. 7A-7D, the slotted sputtering target 416 includes a sculpted work surface 424. The work surface 424 tends to show wear according to a certain pattern after extended use. The wear pattern is governed by the configuration of the particular magnetron sputtering system 10 in which the target is used. Because of the uneven wear, the target needs to be replaced before the entire work surface 424 is used. Sculpting the work surface 424 with the inverse of the wear pattern makes the target more efficient by having a larger percentage of the work surface 424 located at the primary wear areas. The sputtering target 416 includes a sculpted work surface 424, as best shown in FIG. 7D. The work surface 424 is made up of a plurality of annular rings 428 and the recessed surface 426 is formed by a pattern of trenches 432. The trenches 432 are formed into annular rings in the figures, however, the trenches 432 may be formed into any number of patterns depending on the wear pattern produced by specific sputtering apparatus. Such sculpting of ferromagnetic materials would be difficult without the trenches 432 because a ferromagnetic target according to the prior art would be required to be too thin to allow a substantial amount of sculpting. The trenches 432 allow the target to have a higher working surface with a sufficient pass through flux for a target to therefore allow one to optimally sculpt the work surface.

It should be particularly noted that the percentage of the target surfaces that the work surface 24 takes up is discussed only by way of example. The work surface 24 may take up more or less of the total surface as long as a sufficient pass through flux is achieved. Further, the ratio of the height of the recessed surface 26 to the height of the work surface 24 is discussed by way of example only. The height of the recessed surface 26 is chosen to achieve a sufficient pass through flux, which is controlled by the material the target is made of and the configuration of the magnetron sputtering system the target is used in. The height of the work surface 24 may vary according to other constraints such as available space in the machine or material cost.

While the invention has been described with reference to preferred embodiments, it will be understood by those skilled in the art that various changes may be made and equivalents may be substituted for elements thereof to adapt to particular situations without departing from the scope of the invention. Therefore, it is intended that the invention not be limited to the particular embodiments disclosed as the best mode contemplated for carrying out this invention, but that the invention will include all embodiments falling within the scope and spirit of the appended claims.

1. An extended life sputtering target for depositing a ferromagnetic material onto a substrate in a chamber of a sputtering apparatus using a magnetic field passing through the target to produce a plasma field within the chamber, the target comprising a plate formed from the ferromagnetic material and having a supporting surface, a working surface substantially opposite to the supporting surface and from which atoms of the ferromagnetic material are caused by the plasma field to be detached from the target, the distance between the supporting surface and the working surface being greater than an optimum distance by which a sufficient plasma field can be created, the plate defining a plurality of grooves cut into the working surface and forming both discrete areas on the working surface and a recessed surface between the supporting surface and the working surface, the distance between the recessed surface and the supporting surface being sufficiently small and the area of the recessed surface being sufficiently large such that the plasma field in the chamber is sufficient to detach ferromagnetic material atoms from the working surface.

2. The target of claim 1, wherein the ferromagnetic material is selected from a group consisting essentially of nickel, cobalt, iron, and alloys thereof.

3. The target of claim 2, wherein the ferromagnetic material is an alloy with up to 40 atomic % boron.

4. The target of claim 2, wherein the ferromagnetic material is an alloy with up to 25 atomic % boron.

5. The target of claim 1, wherein the discrete areas comprise a plurality of substantially circular surface sections.

6. The target of claim 5, wherein the discrete areas further comprise a plurality of substantially hypocycloidal surface sections interspersed between the circular surface sections.

7. The target of claim 1, wherein the discrete areas comprise a plurality of substantially rectangular surface sections.

8. The target of claim 1, wherein the discrete areas comprise a plurality of spaced annular rings and the recessed surface is formed both by annular grooves surrounding the rings and by the spaces within the annular rings..

9. The target of claim 1, wherein the working surface is non-planar such that the distance between the support surface and each discrete area of the working surface is substantially proportional to the rate of detachment of the atoms from that discrete area by the sputtering apparatus.

10. The target of claim 1, in which the plate comprises a substantially circular outer perimeter.

11. The target of claim 1, in which the plate comprises a substantially polygonal outer perimeter.

12. The target of claim 1, in which the plate comprises a substantially rectangular outer perimeter.

13. A magnetron sputtering system comprising means for defining a vacuum chamber, means for producing an ionized gas to be contained in the chamber, an electromagnet proximate to the vacuum chamber; and an extended life sputtering target according to claim 1 positioned within the chamber adjacent the electromagnet, the electromagnet forming the ionized gas into a torus shaped plasma field proximate to the working surface to detach atoms from the working surface.

14. The magnetron sputtering system of claim 11, wherein the working surface of the target is non-planar such that the distance between the support surface and each discrete area of the working surface is substantially proportional to the rate of detachment of atoms from that discrete area.

15. A magnetron sputtering system comprising means for defining a vacuum chamber, means for producing an ionized gas to be contained in the chamber, an electromagnet proximate to the vacuum chamber; and an extended life sputtering target according to claim 3 positioned within the chamber adjacent the electromagnet, the electromagnet forming the ionized gas into a torus shaped plasma field proximate to the working surface to detach atoms from the working surface.
